(19) United States
(12) Patent Application Publication
(10) Pub. No.: US 2022/0369505 A1
(43) Pub. Date: Nov. 17, 2022

(54) ELECTRONIC APPARATUS COOLING DEVICE, WATER-COOLED INFORMATION PROCESSING DEVICE, COOLING MODULE, AND ELECTRONIC APPARATUS COOLING METHOD

(71) Applicant: NEC Corporation, Minato-ku, Tokyo (JP)

(72) Inventor: Yoichi MIZUKO, Tokyo (JP)

(73) Assignee: NEC Corporation, Minato-ku, Tokyo (JP)

(21) Appl. No.: 17/620,185

(22) PCT Filed: May 26, 2020
(86) PCT No.: PCT/JP2020/020659

§ 371 Date: Dec. 17, 2021

(30) Foreign Application Priority Data
Aug. 27, 2019 (JP) 2019-154567

(51) Int. Cl. H05K 7/20; G06F 1/20

(52) U.S. Cl. CPC H05K 7/20254; H05K 7/20172; H05K 7/20272; H05K 7/20409; G06F 1/20; G06F 2200/201

(57) ABSTRACT

An electronic apparatus cooling device is provided with a water-cooling cold plate unit that is disposed in contact with a heat-generating element and that cools the heat-generating element directly by means of a liquid refrigerant that circulates in an inner flow path; an air-cooling fin disposed adjacent or in proximity to the water-cooling cold plate unit and having a fin tube through which the liquid refrigerant is circulated; and a refrigerant supply means that supplies the liquid refrigerant to the inner flow path of the water-cooling cold plate unit and to the fin tube in the air-cooling fin in a distributed manner.

### TECHNICAL FIELD

The present invention relates to an electronic apparatus cooling device that cools an electronic apparatus, a water-cooled information processing device, a cooling module, and an electronic apparatus cooling method.

### BACKGROUND ART

In recent years, CPUs (central processing units) that constitute high performance computers such as used in high-performance computing have come into use.

The power consumption of computers using such high-performance computing (HPC) is high, and so cooling with air is becoming difficult.

In order to solve this problem, cooling is performed by a direct liquid cooling (DLC) method that directly removes the heat of the module by a cold plate in which a liquid refrigerant is circulated.

Specifically, in the cooling module by the DLC method shown in Patent Document 1, a circuit board having a mounting surface parallel to the cooling air is arranged downstream of the cooling air generated by the fan. This circuit board has a plurality of regions in which electronic components are mounted on the mounting surface. A cold plate cooled by a liquid refrigerant is provided in some of these regions, with the electronic components being arranged on the cold plate.

The heating element cooling device shown in Patent Document 2 has a cooling plate in which the power module is arranged in direct contact with the surface.

This cooling plate has an internal flow path through which a low-temperature liquid refrigerant flows. Cooling fins are installed on the surface of the cooling plate.

In such a cooling plate, the power module arranged in contact with the cooling plate is directly cooled by the liquid refrigerant flowing through the internal flow path.

Further, a fan for sending air to cooling fins is provided on the upstream side of the cooling plate shown in Patent Document 2. The air sent by this fan is cooled by passing through the cooling fins. The cooled air is afterward sent to an electric field capacitor located behind the cooling plate to cool the electric field capacitor.

### PRIOR ART DOCUMENTS

### Patent Documents

[Patent Document 1] Japanese Unexamined Patent Application, Publication No. 2014-53504
[Patent Document 2] Japanese Unexamined Patent Application, Publication No. H11-023075

### SUMMARY OF INVENTION

### Problems to be Solved by the Invention

In the cooling devices shown in Patent Documents 1 and 2, air-cooling fins for cooling air supplied from the cooling fan are provided, with the electronic components being cooled by the cooled air. Moreover, a cold plate is provided that directly cools the electronic components by circulating the liquid refrigerant.

However, in such a cooling system, when the volume of the cold plate in contact with a DLC-type electronic apparatus such as a server is large, it becomes difficult to secure the space of the flow path allocated to the air flow for air cooling. For this reason, there is a problem of the efficiency of air cooling deteriorating.

Further, in the cooling method as described above, if a small cold plate is used, the cooling efficiency of water cooling is lowered and the cooling efficiency of air cooling by the attached fins is also lowered. Therefore, in the housing of the server, which is an electronic apparatus, how to maintain efficient cooling for a heat-generating element that requires air cooling other than cooling by the DLC method has become an issue.

The present invention has been made in view of the above circumstances and provides an electronic apparatus cooling device, a water-cooled information processing device, a cooling module, and an electronic apparatus cooling method that can improve the cooling efficiency of an entire electronic apparatus by increasing the cooling efficiency of air-cooling fins.

### Means for Solving the Problems

In order to solve the above problems, the present invention proposes the following means.

This electronic apparatus cooling device according to the first aspect of the present invention includes: a water-cooling cold plate unit that is disposed in contact with a heat-generating element and that cools the heat-generating element directly by means of a liquid refrigerant that circulates in an inner flow path; an air-cooling fin disposed adjacent or in proximity to the water-cooling cold plate unit and having a fin tube through which the liquid refrigerant is circulated; and a refrigerant supply means that supplies the liquid refrigerant to the inner flow path of the water-cooling cold plate unit and to the fin tube in the air-cooling fin in a distributed manner.

The cooling module according to the second aspect of the present invention includes: a water-cooling cold plate unit that is disposed in contact with a heat-generating element and that cools the heat-generating element with a liquid refrigerant that circulates in an inner flow path; and an air-cooling fin integrally formed on the water-cooling cold plate unit and comprising a fin tube through which the liquid refrigerant is circulated.

The electronic apparatus cooling method according to the third aspect of the present invention includes: water-cooing a heat-generating element by circulating a liquid refrigerant in an inner flow path of a cold plate unit that is disposed in contact with the heat-generating element, air-cooling a heat-generating element disposed downstream of an air-cooling fin by disposing in the air-cooling fin a fin tube through which the liquid refrigerant is circulated; and supplying the liquid refrigerant to the cold plate unit and the fin tube in a distributed manner.

### Advantageous Effects of the Invention

According to the cooling device of the present invention, it is possible to maintain air-cooling performance at a constant level and raise the cooling efficiency of an entire electronic apparatus regardless of the size of a water-cooling cold plate by supplying a liquid refrigerant to a fin tube in an air-cooling fin.

### BRIEF DESCRIPTION OF DRAWINGS

FIG. 1 is a cross-sectional view showing a cooling device according to a minimum configuration example of the present invention.

FIG. 2 is a perspective view showing a rack-mounted server including a cooling device according to an embodiment of the present invention.

FIG. 3 is a perspective view showing a cooling device used in the rack mount server shown in FIG. 2.

FIG. 4 is a front view showing a water-cooling cold plate unit, an air-cooling fin, and a refrigerant supply means in the cooling device shown in FIG. 3.

FIG. 5 is a perspective view showing the flow of air supplied to the air-cooling fins shown in FIG. 4.

FIG. 6 is a development view of the water-cooling cold plate unit and the air-cooling fin shown in FIG. 4.

FIG. 7A is a plan view showing a DLC-type server according to a comparative example.

FIG. 7B is a plan view showing a DLC-type server according to the present invention.

FIG. 8 is a perspective view showing a DLC-type server according to the comparative example shown in FIG. 7A.

### EXAMPLE EMBODIMENTS

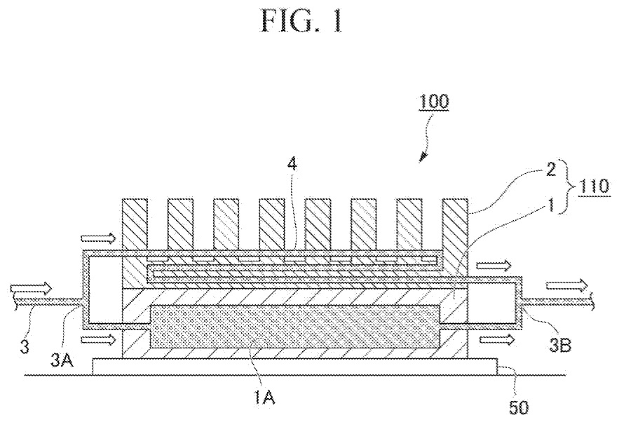

A cooling device 100 according to the minimum configuration example of the present invention will be described with reference to FIG. 1.

The cooling device 100 includes a water-cooling cold plate unit 1, air-cooling fin 2, and a refrigerant supply means 3. The water-cooling cold plate unit 1 and the air-cooling fin 2 form a cooling module 110.

The water-cooling cold plate unit 1 is arranged so as to come into contact with a heat-generating element 50 to be cooled. The water-cooling cold plate unit 1 is configured to directly cool the heat-generating element 50 with liquid refrigerant flowing through an internal flow path 1A.

The air-cooling fin 2 is arranged adjacent to and integrated with the water-cooling cold plate unit 1 or in the vicinity of the water-cooling cold plate unit 1. The air-cooling fin 2 has inside a fin tube 4 through which the liquid refrigerant flows.

The refrigerant supply means 3 supplies the liquid refrigerant to the internal flow path 1A of the water-cooling cold plate unit 1 and the fin tube 4 in the air-cooling fins 2. The refrigerant supply means 3 supplies the liquid refrigerant to the internal flow path 1A and the fin tube 4 in a distributed manner via branch portions 3A and 3B.

According to the cooling device 100 of the present invention described above, a part of the liquid refrigerant supplied to the internal flow path 1A of the water-cooling cold plate unit 1 is supplied to the fin tube 4 in the air-cooling fin 2 by the refrigerant supply means 3.

As a result, in the cooling device 100, the air-cooling fin 2 is cooled by the liquid refrigerant supplied to the fin tube 4. Accordingly, the air cooling performance of the air-cooling fin 2 can be improved. Thereby, the heat-generating element located downstream of the air flow can be efficiently cooled by the cold air that has passed through the cooling fin 2.

That is, in the cooling device 100, the liquid refrigerant is supplied to the fin tube 4 in the air-cooling fin 2 in a distributed manner. Thereby, the air cooling performance of the air-cooling fin 2 can be maintained at a constant level regardless of the size of the water-cooling cold plate unit 1. As a result, it is possible to increase the cooling efficiency of the entire cooling device 100.

The cooling module 110 provided in the cooling device 100 has the water-cooling cold plate unit 1 that is arranged in contact with the heat-generating element 50 and directly cools this heat-generating element with a liquid refrigerant flowing through an internal flow path. Further, the cooling module 110 includes the air-cooling fin 2 formed integrally with the water-cooling cold plate unit 1 and having a fin tube 4 through which the liquid refrigerant flows.

In the cooling device 100, there is a water cooling stage of directly cooling a heat-generating element by flowing a liquid refrigerant through the internal flow path 1A of the water-cooling cold plate unit 1 arranged in contact with the heat-generating element 50, an air-cooling stage of air-cooling the heat-generating element by arranging the fin tube 4 through which the refrigerant flows in the air-cooling fin 2, and a refrigerant supply stage of supplying liquid refrigerant to the water-cooling cold plate unit 1 of the water-cooling stage and the fin tube 4 of the air-cooling stage in a distributed manner.

### Embodiment

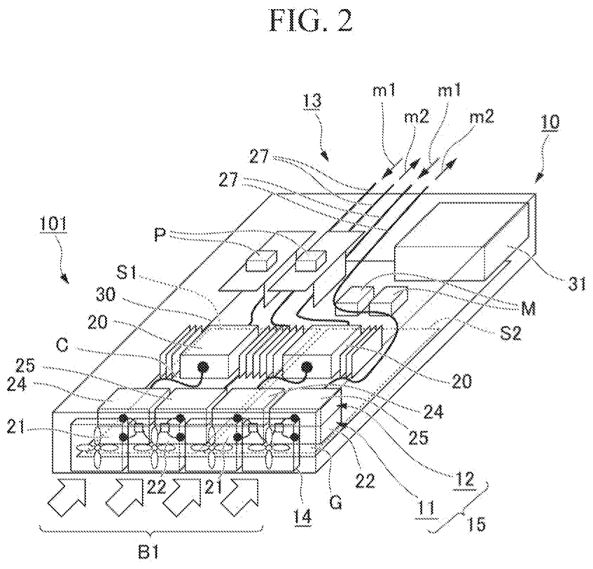

A cooling device 101 of the water-cooled information processing device according to the embodiment of the present invention will be described with reference to FIGS. 2 to 8.

The cooling device 101 according to the present embodiment is a DLC-type server applied to a rack-mounted server 10 or the like for mounting a 1U (19-inch standard) GPGPU (general-purpose computing on graphics processing unit) function.

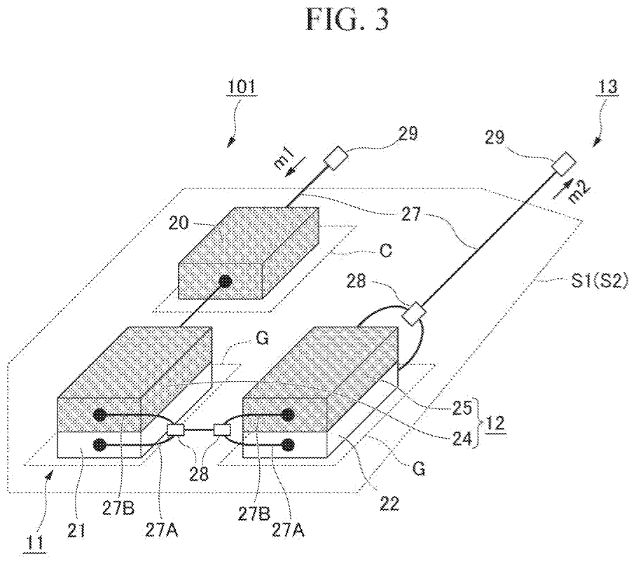

As shown in FIGS. 2 and 3, a processing unit G provided with a GPGPU function, a calculation means C consisting of a CPU (central processing unit), serving as heat-generating elements, and a communication means P consisting of a PCI-e (peripheral component interconnect express) are mounted on a main board 30 of the rack-mounted server 10. Moreover, various storage means M including a DRAM (dynamic random access memory), an MRAM (magnetoresistive random access memory), an HDD (hard disk drive), an SSD (solid state drive), a non-volatile memory, and the like are installed on the main board 30.

A power supply unit 31 made of a PSU (power supply unit) is also mounted on the rear part of the main board 30.

The processing unit G and the calculation means C, which generate a large amount of heat, are located on the front side of the main board 30, while the communication means P composed of the PCI-e, the storage means M, and the power supply unit 31 consisting of the PSU are located on the rear side of the main board 30.

As shown in FIGS. 2 and 3, the cooling device 101 installed in the rack-mounted server 10 has cold plate sets S1 and S2 provided on the left and right sides of the main board 30 for cooling the heat-generating elements described above. Each of the cold plate sets S1 and S2 includes a water-cooling cold plate unit 11, an air-cooling fin 12, a refrigerant supply means 13, and an air fan 14.

In the aforementioned constituent elements, a cooling module 15 is constituted by the water-cooling cold plate unit 11 and the air-cooling fin 12.

The present embodiment illustrates a commercially available 1U size rack-mounted server with four processing units G each having a GPGPU function (hereinafter, also referred to as GPGPU units) at the front and two calculation means C on the rear side of the GPGPU units G Due to cooling restrictions, two sets of cold plate sets S1 and S2 are used, with two GPGPU units G and one CPU on each of the left and right sides of the main board 30 serving as one set.

That is, the cold plate sets S1 and S2 of the present embodiment carry out cooling of the server equipped with the GPGPU function by being divided into the cold plate set S1 on the right side and the cold plate set S2 on the left side.

Hereinbelow, the water-cooling cold plate unit 11, the air-cooling fin 12, the refrigerant supply means 13, and the air fan 14 provided in the cold plate sets S1 and S2 will be described in order.

As shown in FIG. 3, the water-cooling cold plate unit 11 is constituted by one cold plate 20 for cooling the CPU (C) and two cold plates 21 and 22 for cooling the GPGPU units G being arranged in series.

The two cold plates 21 and 22 are arranged at a front position closer to the air fan 14 than the cold plate 20 in order to efficiently cool the GPGPU units G, which generate a large amount of heat.

These cold plates 20 to 22 directly cool the CPU (C) and the GPGPU units G arranged in contact with the lower surfaces thereof by the liquid refrigerant flowing through the refrigerant supply means 13 in the internal flow path (not shown).

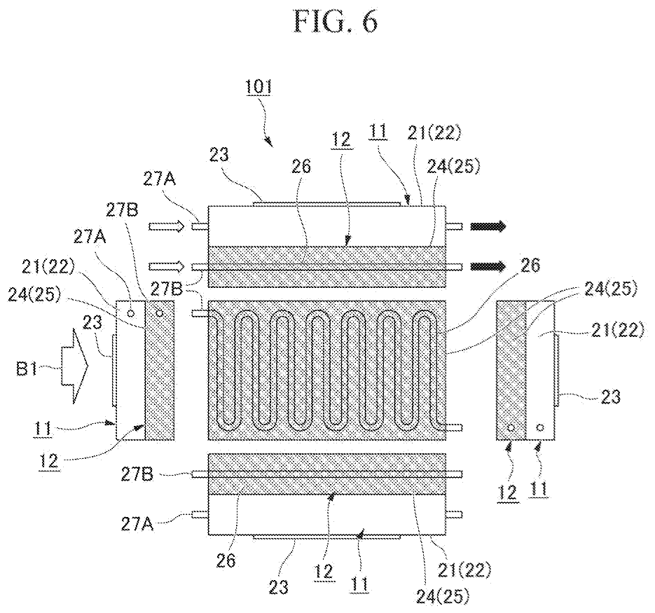

These cold plates 20 to 22 are fixed in a close-contact state on the CPU (C) and the GPGPU units G by interposing a heat conductive layer 23 (see FIG. 6) made of a deformable and highly heat conductive material such as grease.

As shown in FIGS. 3 to 6, the air-cooling fin 12 has heat radiating plates 24 and 25 respectively arranged in contact with upper part of the two cold plates 21 and 22 for the GPGPU units G.

The heat radiating plates 24 and 25 on the cold plates 21 and 22 each have therein a fin tube 26 through which the liquid refrigerant flows.

The refrigerant supply means 13 has a refrigerant hose 27 for supplying liquid refrigerant to the internal flow path (not shown) of the water-cooling cold plate unit 11 and the fin tubes 26 in the heat radiating plates 24 and 25 constituting the air-cooling fin 12.

The refrigerant hose 27 is branched into hoses 27A and 27B via a branch manifold 28, with the liquid refrigerant being supplied to the internal flow paths (not shown) of the cold plates 21 and 22 via the hose 27A. The fin tube 26 is connected to the hose 27B, with the liquid refrigerant being supplied to the heat radiating plates 24 and 25 of the air-cooling fin 12 via this fin tube 26.

As can be seen with reference to the plan view portion of FIG. 6, the fin tube 26 is arranged so as to meander in the heat radiating plates 24 and 25 of the air-cooling fin 12, thereby cooling the entirety of the heat radiating plates 24 and 25 of the air-cooling fin 12.

A quick connector 29 for easily connecting to a cooling water circulation device (CDU: coolant distribution unit) (not shown) is provided at each terminal of the refrigerant hose 27 of the refrigerant supply means 13 (see FIG. 3). At the quick connectors 29, the liquid refrigerant is supplied into the refrigerant hose 27 as shown by the arrow m1, and the liquid refrigerant that has passed through the refrigerant hose 27 is discharged as shown by the arrow m2.

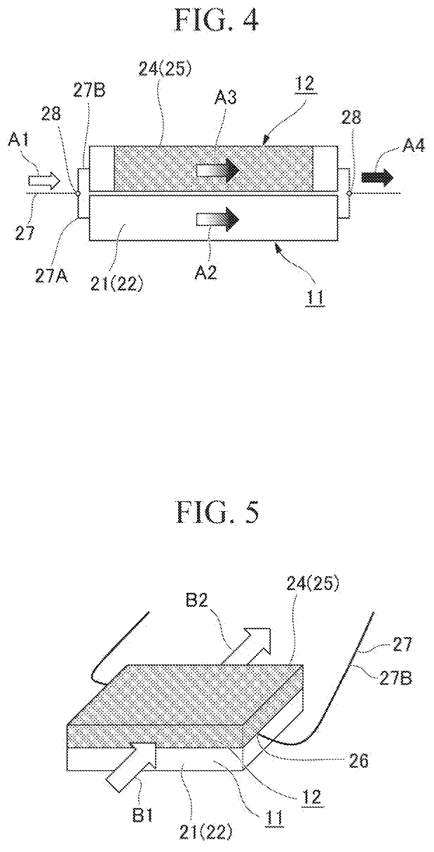

As shown by arrows A1 to A2 to A4 in FIG. 4, in the refrigerant supply means 13 as described above, the liquid refrigerant separated into the hose 27A of the refrigerant hose 27 via the branch manifold 28 is sequentially distributed via the cold plates 20 to 22 provided as the water-cooling cold plate unit 11. Thereby, the liquid refrigerant directly cools the CPU (C) and the GPGPU units G in contact with the cold plates 20 to 22.

In the refrigerant supply means 13, as shown by arrows A1 to A3 to A4 in FIG. 4, the liquid refrigerant separated into the hose 27B of the refrigerant hose 27 via the branch manifold 28 flows through the fin tube 26 installed so as to meander in the heat radiating plates 24 and 25 of the air-cooling fin 12.

In the fin tube 26, the liquid refrigerant moves in a meandering manner in the heat radiating plates 24 and 25 of the air-cooling fin 12, whereby the entirety of the heat radiating plates 24 and 25 is uniformly cooled, and the air passing through the heat radiating plates 24 and 25 is also efficiently cooled.

The air fan 14 is installed on the front end side of the rack-mounted server 10. As shown by arrows B1 and B2 in FIGS. 2 and 5, the air fan 14 cools the air taken in from the outside by causing the air to pass the heat radiating plates 24 and 25 of the air-cooling fin 12 that were cooled by the fin tube 26.

Subsequently, the air that has passed the air-cooling fin 12 passes through the PCI-e (P), the storage means (M), and the PSU (31) located on the rear side of the main board 30. Thereby, the cooling air is discharged to the outside through a rear opening (not shown) after cooling these devices.

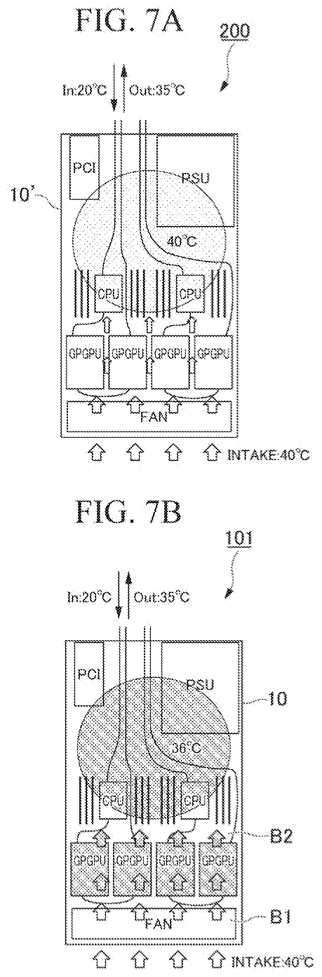

As shown in FIG. 7B, in the cooling device 101 as described above, it was confirmed that, since the air-cooling fin 12 is cooled by the liquid refrigerant passing in a meandering manner through the fin tubes 26 provided in the heat radiating plates 24 and 25 of the air-cooling fin 12, the air at 40° C. sucked in from the air fan 14 drops to 36° C. at the rear position of the cold plates 20 to 22.

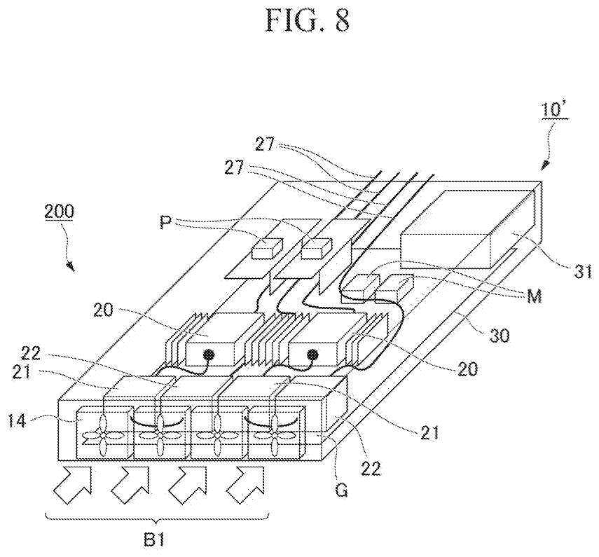

Hereinbelow, the above-described embodiment will be described in comparison with a cooling device 200 of a comparative example shown in FIG. 8. In the cooling device 200 of the rack-mounted server 10′ shown in the comparative example of FIG. 8, constitutions that are the same as those of the cooling device 100 according to the present embodiment of FIG. 2 are designated by the same reference numerals.

The cooling device 200 of the rack-mounted server 10′ shown in FIG. 8 consists of the water-cooling cold plate unit 11 without the fin tube 26 and the air-cooling fin 12. In this cooling device 200, as shown in FIG. 7A, the 40° C. air sucked from the fan 14 is in a state of not being cooled, and so the temperature remains 40° C. even at the rear position of the cold plates 20 to 22. Therefore, it is inevitable that the cooling capacity downstream of the cooling air will be lower than that of the embodiment.

In the refrigerant hoses 27 of both the cooling device 101 of the present embodiment and the cooling device 200 shown in the comparative example, a liquid refrigerant of 20° C. is supplied as indicated by the notation In, and a liquid refrigerant having a temperature of 35° C. is discharged as indicated by the notation Out, whereby heat is absorbed through the cold plates 20 to 22 (and the air-cooling fin 12).

That is, in the cooling device 101 of the present embodiment, by juxtaposing the air-cooling fin 12 having the fin tube 26 to the water-cooling cold plate unit 11, it is possible to cool the air sucked in by the air fan 14 and make that cold air reach the rear of the main board 30 as shown in FIGS. 7A and 7B.

As a result, in the present embodiment, it is possible to supply low-temperature cooling air to devices such as the PCI-e (P) and PSU 31 located at the rear side of the main board 30.

As described in detail above, according to the cooling device 101 according to the present embodiment, a part of the liquid refrigerant supplied to the internal flow path (not shown) of the water-cooling cold plate unit 11 is supplied to the fin tube 26 in the air-cooling fin 12, which is an air cooling means, in a distributed manner by the refrigerant supply means 13.

As a result, in the cooling device 101, the air cooling performance of the air-cooling fin 12 can be improved by the liquid refrigerant supplied in a distributed manner to the fin tube 26. Accordingly, a heat-generating element located downwind of the air-cooling fin 12 can be efficiently cooled by the cold air that has been heat-exchanged through the air-cooling fin 12.

That is, in the cooling device 101 according to the present embodiment, by supplying the liquid refrigerant in a distributed manner to the fin tube 26 in the air-cooling fin 12, the air-cooling performance of the air-cooling fin 12 can be maintained constant regardless of the size of the water-cooling cold plate unit 11, and as a result, the overall cooling efficiency can be improved.

More specifically, as the first effect, it is possible to supply air cooled by heat exchange to the downwind side while cooling the GPGPU and CPU, with the CDU (heat exchanger) and manifold, which are conventional DLC equipment, remaining as is. Thereby, it is possible to secure the capacity of cooling to downwind-side devices to prevent heating of the downwind-side devices, and so further improve the reliability of the operation thereof.

A second effect is that the equipment (CDU (heat exchanger)) and manifold of a conventional DLC can be used as is, which enables low-cost and highly efficient cooling.

A third effect is that, even in an energy-saving data center that is a high temperature environment, cold air can be supplied to the air-cooled part downstream, and so it is possible to increase the cooling ratio of water cooling even without a separate cooling device such as a side cooler or a water-cooled rear door.

A fourth effect is that, since there is no need to use a side cooler or a water-cooled rear door, a water-cooling system with high cooling efficiency can be realized at low cost.

In the above embodiment, the air-cooling fin 12 is brought into contact with and integrally joined to the water-cooling cold plate unit 11, but the present invention is not limited thereto. That is, the air-cooling fin 12 may be arranged in the vicinity of the water-cooling cold plate unit 11.

In addition, in the above embodiment, the water-cooling cold plate unit 11 having the three cold plates 20 to 22 and the air-cooling fin 12 consisting of the two heat radiating plates 24 and 25 installed on the cold plates 21 and 22 are provided as the cold plate sets S1 and S2. The number of these cold plates and heat radiating plates installed is not limited to the above embodiment, and can be freely determined according to specifications such as equipment layout and cooling capacity (calorific value).

Although embodiments of the present invention have been described in detail with reference to the drawings, the specific configuration is not limited to this embodiment, and design changes and the like within a range not deviating from the gist of the present invention are also included.

Priority is claimed on Japanese Patent Application No. 2019-154567, filed Aug. 27, 2019, the content of which is incorporated herein by reference.

### INDUSTRIAL APPLICABILITY

The present invention can be used as an electronic apparatus cooling device that can efficiently cool an electronic apparatus installed on a board, a water-cooled information processing device, a cooling module, and an electronic apparatus cooling method.

### DESCRIPTION OF THE REFERENCE SYMBOLS

1: Water-cooling cold plate
2: Air-cooling fin
3: Refrigerant supply means
4: Fin tube
10: Rack-mounted server
11: Water-cooling cold plate unit
12: Air-cooling fin
13: Refrigerant supply means
14: Air fan
15: Cooling module
20: Cold plate
21: Cold plate
22: Cold plate
23: Heat conductive layer
24: Heat radiating plate
25: Heat radiating plate
26: Fin tube
27: Refrigerant hose
28: Branch manifold
29: Quick connector
30: Main board
31: Power supply unit
50: Heat-generating element
100: Cooling device
101: Cooling device
110: Cooling module
G: Processing unit
C: Calculation means
P: Communication means
M: Memory

What is claimed is:

1. An electronic apparatus cooling device comprising:
a water-cooling cold plate unit that is disposed in contact with a heat-generating element and that cools the heat-generating element directly by means of a liquid refrigerant that circulates in an inner flow path;
an air-cooling fin disposed adjacent or in proximity to the water-cooling cold plate unit and having a fin tube through which the liquid refrigerant is circulated; and
a refrigerant supplier that supplies the liquid refrigerant to the inner flow path of the water-cooling cold plate unit and to the fin tube in the air-cooling fin in a distributed manner.

2. The electronic apparatus cooling device according to claim 1, wherein the refrigerant supply means comprises a branch manifold that distributes the liquid refrigerant to the inner flow path of the water-cooling cold plate unit and to the fin tube in the air-cooling fin.

3. The electronic apparatus cooling device according to claim 1, wherein the fin tube is arranged in the air-cooling fin in a bent state.

4. The electronic apparatus cooling device according to claim 1, further comprising an air fan that sends air to the air-cooling fin,
wherein the air fan blows the air to a heat-generating element located downwind of the air fan after passing the air over the air-cooling fin.

5. The electronic apparatus cooling device according to claim 1, wherein the water-cooling cold plate unit is a direct liquid cooling unit for a general-purpose computing on graphics processing unit (GPGPU).

6. The electronic apparatus cooling device according to claim 1, wherein a second water-cooling cold plate unit, which is a direct liquid-cooled unit for a central processing unit (CPU), is arranged in series in the water-cooling cold plate unit.

7. The electronic apparatus cooling device according to claim 1, wherein heat-generating elements including a central processing unit (CPU), a peripheral component interconnect (PCI), and a power supply unit (PSU) are installed on the downwind-side of the air-cooling fin.

8. (canceled)

9. A cooling module comprising:
a water-cooling cold plate unit that is disposed in contact with a heat-generating element and that cools the heat-generating element with a liquid refrigerant that circulates in an inner flow path; and
an air-cooling fin integrally formed on the water-cooling cold plate unit and comprising a fin tube through which the liquid refrigerant is circulated.

10. An electronic apparatus cooling method comprising:
directly water-cooling a heat-generating element by circulating a liquid refrigerant in an inner flow path of a cold plate unit that is disposed in contact with the heat-generating element;
air-cooling a heat-generating element disposed downstream of an air-cooling fin by disposing in the air-cooling fin a fin tube through which the liquid refrigerant is circulated; and
supplying the liquid refrigerant to the cold plate unit and the fin tube in a distributed manner.
